(19) United States
(12) Patent Application Publication
(10) Pub. No.: US 2024/0402506 A1
(43) Pub. Date: Dec. 5, 2024

(54) OPTOELECTRONIC ASSEMBLY

(71) Applicant: ams-OSRAM International GmbH, Regensburg (DE)

(72) Inventors: Nicole BERNER, Walderbach (DE); Jörg Erich SORG, Regensburg (DE); Karsten AUEN, Regensburg (DE)

(73) Assignee: ams-OSRAM International GmbH, Regensburg (DE)

(21) Appl. No.: 18/262,773

(22) PCT Filed: Dec. 20, 2021
(86) PCT No.: PCT/EP2021/086835

§ 371 Date: Jul. 25, 2023

(30) Foreign Application Priority Data
Feb. 1, 2021 (DE) 102021102254.1

(51) Int. Cl. G02B 27/09; G02B 27/14; G03B 21/20; H01S 5/40

(52) U.S. Cl. CPC G02B 27/0905; G02B 27/145; G03B 21/2013; G03B 21/2033; H01S 5/4012; H01S 5/4031; H01S 5/4087

(57) ABSTRACT

The invention relates to an optoelectronic assembly including at least two semiconductor laser components, which are designed to emit electromagnetic radiation, and an optical superpositioning element with at least one radiation inlet surface and a radiation outlet surface. Each semiconductor laser component is paired with a respective optical element, and each semiconductor laser component emits an inlet beam bundle or a plurality of spatially separated inlet beam bundles. All of the inlet beam bundles of a semiconductor laser component pass through the respective paired optical element, wherein a plurality of inlet beam bundles emitted by a semiconductor laser component are fanned out relative to each other after passing through the optical element such that the inlet beam bundles enter the optical superpositioning element at different inlet angles. Inlet beam bundles from different semiconductor laser components exit together at the radiation outlet surface of the optical superpositioning element in a plurality of outlet beam bundles.

### CROSS-REFERENCE TO RELATED APPLICATIONS

The present application is a national stage entry from International Application No. PCT/EP2021/086835, filed on Dec. 20, 2021, published as International Publication No. WO 2022/161705 A1 on Aug. 4, 2022, and claims priority to German Patent Application No. 10 2021 102 254.1, filed Feb. 1, 2021, the disclosures of all of which are hereby incorporated by reference in their entireties.

### FIELD OF THE INVENTION

An optoelectronic assembly is disclosed. The optoelectronic assembly is in particular configured to generate electromagnetic radiation, for example light that is perceptible to the human eye.

### BACKGROUND OF THE INVENTION

A problem to be solved is to specify an optoelectronic assembly that emits electromagnetic radiation with an increased spectral bandwidth.

### SUMMARY OF THE INVENTION

According to at least one embodiment of the optoelectronic assembly, the optoelectronic assembly comprises at least two semiconductor laser components which are configured to emit an electromagnetic radiation. A semiconductor laser component is in particular configured to emit coherent or partially coherent electromagnetic radiation. A semiconductor laser component advantageously emits electromagnetic radiation with a small spectral bandwidth, a low divergence and a high beam intensity.

According to at least one embodiment of the optoelectronic assembly, the optoelectronic assembly comprises an optical superpositioning element having at least one radiation inlet surface and one radiation outlet surface. In particular, the radiation inlet surface is provided for coupling electromagnetic radiation into the optical superpositioning element. For example, the optical superpositioning element comprises a plurality of radiation inlet surfaces on different sides of the optical superpositioning element. In particular, the radiation inlet surface and/or the radiation outlet surface include an anti-reflection layer. An anti-reflection layer can advantageously reduce or avoid an undesired reflection of electromagnetic radiation at the radiation inlet surfaces and the radiation outlet surface of the optical superpositioning element.

The optical superpositioning element is configured to superimpose beams entering the optical superpositioning element via the radiation inlet surface and to allow them to exit from the radiation outlet surface. In particular, the optical superpositioning element is formed with a radiation transmitting material. For example, the optical superpositioning element has a plurality of reflective surfaces configured to reflect and redirect electromagnetic radiation. Preferably, some reflective surfaces exhibit wavelength-dependent reflectivity. In particular, the reflective surfaces may be at least partially formed as dichroic mirrors. Reflective surfaces can further be formed as λ/4-platelets to change a polarization of an incident electromagnetic radiation.

According to at least one embodiment of the optoelectronic assembly, an optical element is assigned to each semiconductor laser component. The optical element is, for example, a lens. The optical element is formed in particular with a radiation-transmitting material. For example, the optical element serves to change the propagation direction and/or divergence of a beam of radiation passing through the optical element. Going further, a plurality of optical elements may be formed in a coherent optical structure. The use of a contiguous optical structure can advantageously reduce an adjustment effort, since the optical elements are firmly connected to each other therein.

According to at least one embodiment of the optoelectronic assembly, each semiconductor laser component emits an inlet beam bundle or a plurality of spatially separated inlet beam bundles. In particular, a semiconductor laser component emits a plurality of inlet beam bundles and a semiconductor laser component emits an inlet beam bundle. For example, the inlet beam bundles propagate in a emission direction. Preferably, the inlet beam bundles are aligned parallel to each other and emerge from the semiconductor laser component, for example, perpendicular to a radiation outlet surface of the semiconductor laser component. For example, an inlet beam bundle is a Gaussian beam.

The inlet beam bundles impinge on the radiation inlet surface of the optical superpositioning element at an inlet distance from each other. An inlet distance is a shortest distance between two inlet beam bundles on the radiation inlet surface of the optical superpositioning element. Preferably, the inlet distance between all inlet beam bundles of a semiconductor laser component is the same.

According to at least one embodiment of the optoelectronic assembly, all inlet beam bundles of a semiconductor laser component pass through the respectively assigned optical element, wherein several inlet beam bundles emitted by a semiconductor laser component are fanned out from one another after passing through the optical element in such a way that the inlet beam bundles enter the optical superpositioning element at different entry angles. Preferably, one of the inlet beam bundles hits the inlet surface of the optical superpositioning element perpendicularly.

According to at least one embodiment of the optoelectronic assembly, inlet beam bundles from different semiconductor laser components emerge from the radiation outlet surface of the optical superpositioning element in a plurality of outlet beam bundles superimposed with each other. The outlet beam bundles have an outlet distance. The outlet distance corresponds to a shortest distance of two outlet beam bundles to each other on the radiation outlet surface of the optical superpositioning element. Preferably, all outlet beam bundles have the same outlet distance to each other.

In other words, inlet beam bundles from different semiconductor laser components are superimposed at a common point on the radiation outlet surface of the optical superpositioning element. Thus, a plurality of inlet beam bundles from different semiconductor laser components are imaged in one outlet beam bundle. The outlet beam bundles superimposed at a common point preferably exit the optical superpositioning element at a common exit angle. For example, different outlet beam bundles exit the radiation outlet surface of the optical superpositioning element at different exit points and at different exit angles with respect to each other. Preferably, the outlet beam bundles are fanned out relative to each other.

According to at least one embodiment of the optoelectronic assembly, the optoelectronic assembly comprises
at least two semiconductor laser components configured to emit electromagnetic radiation, and
an optical superpositioning element having at least one radiation inlet surface and one radiation outlet surface, wherein
an optical element is assigned to each semiconductor laser component,
each semiconductor laser component emits an inlet beam bundle or a plurality of spatially separated inlet beam bundles,
all inlet beam bundles of a semiconductor laser component pass through the respectively associated optical element, a plurality of inlet beam bundles emitted by a semiconductor laser component being fanned out with respect to one another after passing through the optical element in such a way that the inlet beam bundles enter the optical superpositioning element at different entry angles, and
inlet beam bundles from different semiconductor laser components emerge from the radiation outlet surface of the optical superpositioning element in a plurality of outlet beam bundles superimposed with each other.

An optoelectronic assembly described here is based, among other things, on the following considerations: Semiconductor laser components are particularly suitable for producing a compact optical arrangement for use in a portable system. With semiconductor laser components, electromagnetic radiation with a particularly high beam intensity can be generated in a small solid angle, so that they are particularly suitable for use in display units or projection devices. However, when a laser component is used in a visible wavelength range, undesirable interference effects, for example in the form of speckles, can sometimes be perceived by an observer. These interference effects lead to uneven illumination and disturbing patterns. Furthermore, the use of diffractive optics together with electromagnetic radiation with a large coherence length is hampered by additional undesirable interference effects.

The optoelectronic assembly described here makes use, among other things, of the idea of superimposing electromagnetic radiation from a plurality of semiconductor laser components in an optical superpositioning element in order to generate electromagnetic radiation with an increased spectral bandwidth and, consequently, with a reduced coherence length which nevertheless has a sufficiently good beam quality. With the help of optical elements, parallel beam bundles of the semiconductor laser components can be fanned out before entering the optical superpositioning element in order to achieve a particularly simple superposition of beam bundles from different semiconductor laser components in a radiation outlet surface of the optical superpositioning element.

According to at least one embodiment of the optoelectronic assembly, the optical elements are part of the optical superpositioning element. In other words, the optical elements are integrated into the optical superpositioning element. The optical elements may be formed with the same material as the optical superpositioning element. Thus, simplified manufacturing of the integrated optical elements is possible. A distance of the optical elements to the optical superpositioning element results from the geometric dimensions of the optical superpositioning element. An optical superpositioning element designed in this way has a particularly high mechanical stability.

According to at least one embodiment of the optoelectronic assembly, the optical elements have a distance from the optical superpositioning element. The distance is the shortest direct connection between an optical element and the optical superpositioning element. The distance between the optical element and the optical superpositioning element affects the inlet distance of the inlet beam bundle of a semiconductor laser component when it impinges on the radiation inlet surface of the optical superpositioning element. Likewise, a larger distance between the optical superpositioning element and the optical element increases an inlet distance of the inlet beam bundles when incident on the optical superpositioning element.

According to at least one embodiment of the optoelectronic assembly, the distance of each optical element is set such that the inlet beam bundles from different semiconductor laser components emerge from the radiation outlet surface of the optical superpositioning element in common outlet beam bundles superimposed with each other. Each outlet beam bundle comprises at least one inlet beam bundle from each semiconductor laser component. For example, each outlet beam bundle thus forms a white light source independent of further outlet beam bundles.

By means of a plurality of outlet beam bundles, in particular, a representation of multiple pixels is achieved in a projection application. In a good approximation, the distance of the individual optical elements can be selected in such a way that the optical path lengths of the inlet beam bundles from all semiconductor laser components between their exit from the optical element and the radiation outlet surface of the optical superpositioning element are equal.

According to at least one embodiment of the optoelectronic assembly, each semiconductor laser component comprises a plurality of waveguides each emitting an inlet beam bundle. A waveguide is configured to geometrically guide an electromagnetic radiation and, due to its dimensions, influences an oscillation of certain electromagnetic oscillation modes of the radiation. The waveguide is designed, for example, as a ridge waveguide or as a rib waveguide of the respective semiconductor device.

According to at least one embodiment of the optoelectronic assembly, the waveguides of a semiconductor laser component can be driven independently of each other. Due to the possibility of independent, separate control of the individual waveguides of each semiconductor laser component, several pixels can be generated simultaneously via a downstream, movable mirror, which enables a projection with a particularly high resolution and frame rate.

According to at least one embodiment of the optoelectronic assembly, different inlet beam bundles of a semiconductor laser component have different main wavelengths. The main wavelength of an inlet beam bundle is the wavelength at which the electromagnetic radiation of the inlet beam bundle has a global intensity maximum.

Different main wavelengths of the inlet beam bundles of a semiconductor laser component result in an advantageously increased spectral bandwidth of the electromagnetic radiation emitted by a semiconductor laser component. As a result, undesired optical interference effects in the optoelectronic assembly can be reduced or avoided.

According to at least one embodiment of the optoelectronic assembly, corresponding inlet beam bundles of different semiconductor laser components have a different main wavelength. By means of a different main wavelength a spectral broadening of the electromagnetic radiation takes place, which is superimposed in the outlet beam bundles.

According to at least one embodiment of the optoelectronic assembly, the main wavelengths of inlet beam bundles of different semiconductor laser components differ from each other by at least 10 nm, preferably by at least 20 nm. In particular, different semiconductor laser components each emit electromagnetic radiation with a color that can be perceived differently by humans. For example, one semiconductor laser component emits electromagnetic radiation in the red spectral range, another semiconductor laser component emits electromagnetic radiation in a green spectral range, and another semiconductor laser component emits electromagnetic radiation in a blue spectral range. Advantageously, by mixing the electromagnetic radiations of the semiconductor laser components, an electromagnetic radiation can be emitted which has a color locus that lies within a color space spanned by the individual colors of the emitted electromagnetic radiation.

According to at least one embodiment of the optoelectronic assembly, the differences of the main wavelengths of the inlet beam bundles of each semiconductor laser component differ from each other by at least 0.5 nm. Different differences of the main wavelengths of the inlet beam bundles of a semiconductor laser component can advantageously reduce or avoid undesired interference effects.

According to at least one embodiment of the optoelectronic assembly, at least one inlet beam bundle impinges on the optical element outside an optical axis of the optical element. The optical axis of the optical element is preferably a symmetry axis of the optical element. A beam incident on the optical element outside the optical axis undergoes a change in its propagation direction relative to a beam entering on the optical axis. This advantageously results in a fanning out of the inlet beam bundles of a semiconductor laser component.

According to at least one embodiment of the optoelectronic assembly, the optical elements are formed with the same material and/or have the same geometric dimensions. In particular, the optical elements have the same optical properties, preferably the same optical refractive index. In particular, the optical elements have the same optical refractive index for the respective inlet beam bundles passing through them. In other words, the optical elements have the same imaging properties with respect to the imaging of the respective inlet beam bundles passing through them. The refractive index of the optical elements is preferably adapted to the main wavelength of the respective inlet beam bundle passing through them in such a way that an equal focal length results for the optical elements.

Equal geometric dimensions are to be understood here and in the following as equal dimensions within the scope of a manufacturing tolerance. By an identical design of the optical elements, a particularly simple superposition of the inlet beam bundles of different semiconductor laser components in common outlet beam bundles can be achieved.

According to at least one embodiment of the optoelectronic assembly, the optical elements are designed as collimating lenses. In particular, the optical elements are designed as collimating lenses for the inlet beam bundles. For example, the optical elements reduce the divergence of the inlet beam bundles in the fast axis. Collimated inlet beam bundles can be easily and efficiently forwarded to a further optical system, and further application-relevant optics and components can advantageously be designed to be particularly small. Thus, a size of the optoelectronic assembly can be further reduced.

According to at least one embodiment of the optoelectronic assembly, the semiconductor laser components each emit an equal number of inlet beam bundles. The inlet beam bundles of the semiconductor laser components can be superimposed with each other in the optical superpositioning element in such a way that each outlet beam bundle contains exactly one inlet beam bundle from each semiconductor laser component.

According to at least one embodiment of the optoelectronic assembly, at least one semiconductor laser component has a constant waveguide distance. Constant means here and in the following the same size within the scope of a manufacturing tolerance. The waveguide distance is a shortest distance between two adjacent waveguides of a semiconductor laser component. The waveguide distance and consequently a distance between the inlet beam bundles transverse to their emission direction influences a location where the inlet beam bundles impinge on the associated optical element. As a result, an angle of fanning by the optical element is also determined. Preferably, a semiconductor laser component has an equal waveguide distance between all waveguides.

According to at least one embodiment of the optoelectronic assembly, the waveguide distances of all semiconductor laser components are equal. Equal waveguide distances for all semiconductor laser components allow a particularly simple superposition of the inlet beam bundles of different semiconductor laser components in common outlet beam bundles. Together with the use of optical elements of the same design, this enables a particularly simple adjustment of the optical assembly.

An optoelectronic assembly described here is particularly suitable for use in so-called “smart eyewear products” with which augmented reality (AR) or virtual reality (VR) units are realized. The optoelectronic assembly described here can also be used in various projection systems for displaying image content, for example in glasses, close to the eye or for direct projection of an image into a human eye.

### BRIEF DESCRIPTION OF THE DRAWING

Further advantages and advantageous embodiments and further embodiments of the semiconductor laser component result from the following exemplary embodiments shown in connection with the figures.

Showing in:

FIG. 1 a schematic top view of an optoelectronic assembly described herein according to a first exemplary embodiment,

FIG. 2 a schematic top view of an optoelectronic assembly described herein according to a second exemplary embodiment,

FIG. 3 a schematic top view of an optoelectronic assembly described herein according to a third exemplary embodiment,

FIG. 4 a schematic top view of an optoelectronic assembly described herein according to a fourth exemplary embodiment,

FIG. 5 a schematic top view of an optoelectronic assembly described herein according to a fifth exemplary embodiment,

FIG. 6 a schematic top view of an optoelectronic assembly described herein according to a sixth exemplary embodiment, and

FIG. 7 a schematic top view of an optoelectronic assembly described herein according to a seventh exemplary embodiment.

### DETAILED DESCRIPTION

Elements that are identical, similar or have the same effect are given the same reference signs in the figures. The figures and the proportions of the elements shown in the figures are not to be regarded as to scale. Rather, individual elements may be shown exaggeratedly large for better representability and/or for better comprehensibility.

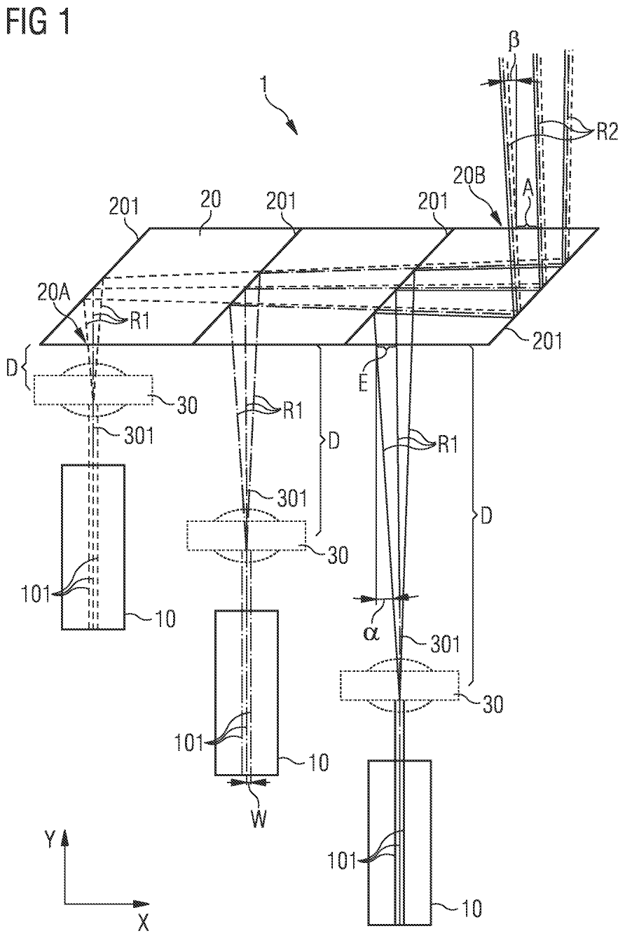

FIG. 1 shows a schematic top view of an optoelectronic assembly 1 described herein according to a first exemplary embodiment. The optoelectronic assembly 1 comprises three semiconductor laser components 10, three optical elements 30 and an optical superpositioning element 20.

Each semiconductor laser component 10 comprises three waveguides 110 and is configured to emit three inlet beam bundles R1. For simplicity, only one central beam of the inlet beam bundles R1 and the outlet beam bundles R2 are shown in each of FIGS. 1, 6, and 7. Each of these central beams represents a complete set of beams forming a laser beam with a certain dimension and divergence. The waveguides 101 of each semiconductor laser component 10 are arranged parallel to each other at a waveguide distance W. The waveguide distances W within the different semiconductor laser components 10 are equal within a manufacturing tolerance.

The semiconductor laser components 10 are aligned parallel to each other. The inlet beam bundles R1 leave the semiconductor laser components 10 in an emission direction Y. A semiconductor laser component 10 is configured to emit electromagnetic radiation in the red spectral range, a semiconductor laser component 10 is configured to emit electromagnetic radiation in the green spectral range, and a semiconductor laser component 10 is configured to emit electromagnetic radiation in the blue spectral range. The main wavelengths of the inlet beam bundles R1 of the semiconductor laser components 10 differ by at least ±10 nm, preferably by at least ±20 nm. The main wavelengths of the inlet beam bundle R1 of the semiconductor laser components 10 differ by 40 nm to 400 nm.

The waveguides 110 within a semiconductor laser component 10 are configured to emit electromagnetic radiation each having a different main wavelength. The differences of the main wavelengths of the inlet beam bundles R1 of each semiconductor laser component 10 differ from each other by at least 0.5 nm.

An optical element 30 is assigned to each semiconductor laser component 10. The optical elements 30 are arranged downstream of the semiconductor laser components 10 in the emission direction. Each optical element 30 has an optical axis 301, which is a symmetry axis of an optical element 30, respectively. The optical elements 30 are collimating lenses to collimate the fast axis of the inlet beam bundle R1, respectively. All optical elements 30 are formed with the same material and have the same refractive index. Furthermore, all optical elements 30 have the same geometric dimensions within a manufacturing tolerance.

The optical superpositioning element 20 is formed with a radiation transmitting material and includes a radiation inlet surface 20A and a radiation outlet surface 20B. The optical superpositioning element 20 includes a plurality of reflective surfaces 201 adapted to reflect and redirect electromagnetic radiation. In particular, some reflective surfaces 201 exhibit a highly wavelength-dependent reflectivity. For example, some reflective surfaces 201 are formed with dichroic mirrors.

At least one inlet beam bundle R1 of each semiconductor laser component 10 enters the optical element 30 outside the optical axis 301 of the respectively associated optical element 30. As a result, the inlet beam bundles R1 are fanned out with respect to each other after passing through the optical element 30. The inlet beam bundles R1 are fanned out such that they enter the optical superpositioning element 20 at different entry angles α. For example, an inlet beam bundle R1 that is perpendicular to an outlet surface of the semiconductor laser component 10 and parallel to the emission direction Y of the semiconductor laser component 10 and has passed through the optical element 30 along its optical axis 301 enters the optical superpositioning element 20 perpendicular to the radiation inlet surface 20A. In contrast, another inlet beam bundle R1 of the same semiconductor laser component 10 that has passed through the optical element 30 outside its optical axis 301 enters the optical superpositioning element at an entry angle α.

The optical elements 30 are each arranged at a distance D from the radiation inlet surface 20A of the optical superpositioning element 20. The distance D of each optical element 30 from the optical superpositioning element 20 influences a lateral inlet distance E that different inlet beam bundles R1 have from each other when entering the optical superpositioning element 20 on the radiation inlet surface 20A. Via the distance D of the individual optical elements 30, it is thus possible to achieve a particularly exact superposition of the inlet beam bundles R1 of all semiconductor laser components 10 in a respective outlet beam bundle R2.

To a good approximation, the distance D can be selected such that an optical path length of the inlet beam bundle R1 of all semiconductor laser components 10 from their exit from the optical element 30 and the radiation outlet surface 20B of the optical superpositioning element 20 is the same. An optical path length is composed of the geometric path length and the refractive index of the irradiated materials along the geometric path. Thus, advantageously, a particularly simple superposition of the inlet beam bundles R1 from different semiconductor laser components 10 in a plurality of outlet beam bundles R2 can be achieved.

Three outlet beam bundles R2 emerge from the radiation outlet surface 20B of the optical superpositioning element 20 at an outlet distance A from each other. In each outlet beam bundle R2, an inlet beam bundle R1 from each of the semiconductor laser components 10 is imaged. Each outlet beam bundle R2 exits the radiation outlet surface 20B at a different exit point and at an exit angle R. Due to the small outlet distance A of the outlet beam bundles R2 from each other and the collimation of the outlet beam bundles R2 still present even after passing through the optical superpositioning element 30, further downstream optics and components can remain small and a system size can be advantageously kept minimal.

Furthermore, due to the different exit angles β of the outlet beam bundle R2 and the possibility of separately driving the individual waveguides 110 of each semiconductor laser component 10, multiple pixels can be generated simultaneously via a downstream movable mirror, enabling projection with a particularly high resolution and frame rate.

For an assumed divergence angle of all semiconductor laser components of 11.25° in the fast-axis and a waveguide distance of 70 μm, the outlet distance is also 70 μm.

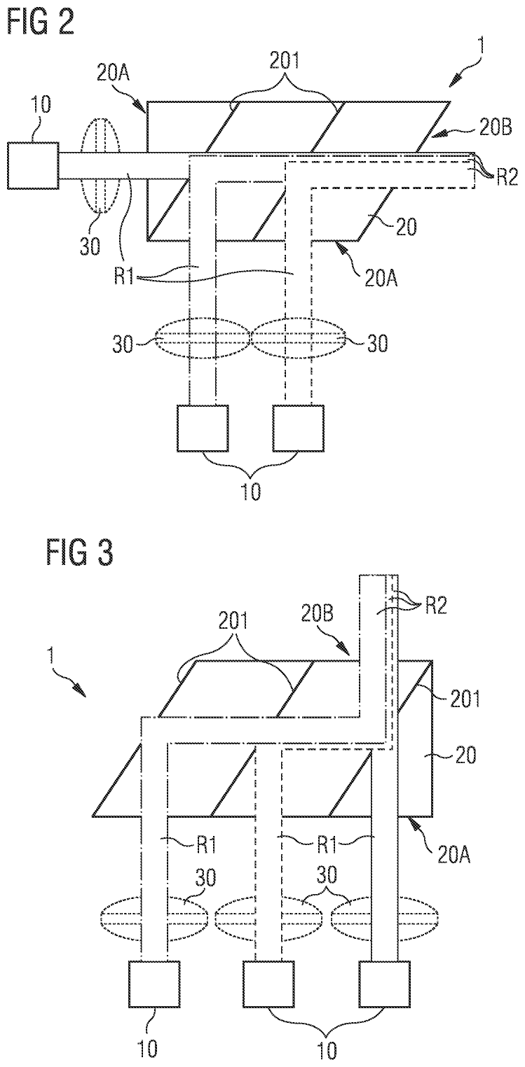

In FIGS. 2 to 5, the inlet beam bundles R1 and the outlet beam bundles R2 are each shown as individual wider beams for simplified illustration. Each beam can also be understood as a plurality of inlet beam bundles R1 or outlet beam bundles R2. Essentially, the second, third, fourth and fifth exemplary embodiments correspond to the first exemplary embodiment shown in FIG. 1.

FIG. 2 shows a schematic top view of an optoelectronic assembly 1 according to the second exemplary embodiment. In contrast to the first exemplary embodiment, the optical superpositioning element 20 comprises two radiation inlet surfaces 20A. Further, the optical superpositioning element comprises two reflective surfaces 201 and can thus be particularly easily fabricated. A semiconductor laser component 10 is aligned transversely to two other semiconductor laser components 10. Consequently, the emission direction Y of a semiconductor laser component 10 is also aligned transversely to the emission direction of two further semiconductor laser components 10.

FIG. 3 shows a schematic top view of an optoelectronic assembly 1 according to the third exemplary embodiment. In contrast to the first exemplary embodiment, the optical superpositioning element 20 has three reflective surfaces 201.

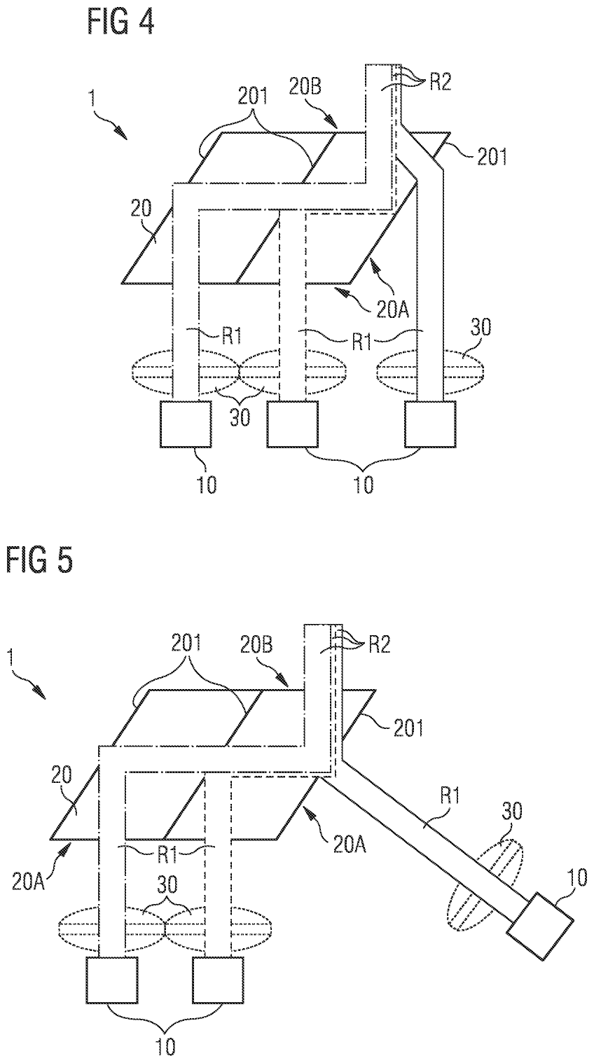

FIG. 4 shows a schematic top view of an optoelectronic assembly 1 according to the fourth exemplary embodiment. In contrast to the first exemplary embodiment, the optical superpositioning element 20 has three reflective surfaces 201. The optical superpositioning element 20 shown in FIG. 4 can be manufactured in a particularly compact manner.

FIG. 5 shows a schematic top view of an optoelectronic assembly 1 according to the fifth embodiment. In contrast to the first exemplary embodiment, the optical superpositioning element 20 comprises two radiation inlet surfaces 20A. Further, the optical superpositioning element 20 comprises three reflective surfaces 201, and thus can be particularly easily fabricated. A semiconductor laser component 10 is oriented transverse with respect to two other semiconductor laser components 10. Consequently, the emission direction Y of a semiconductor laser component 10 is also aligned transverse to the emission direction of two further semiconductor laser components 10.

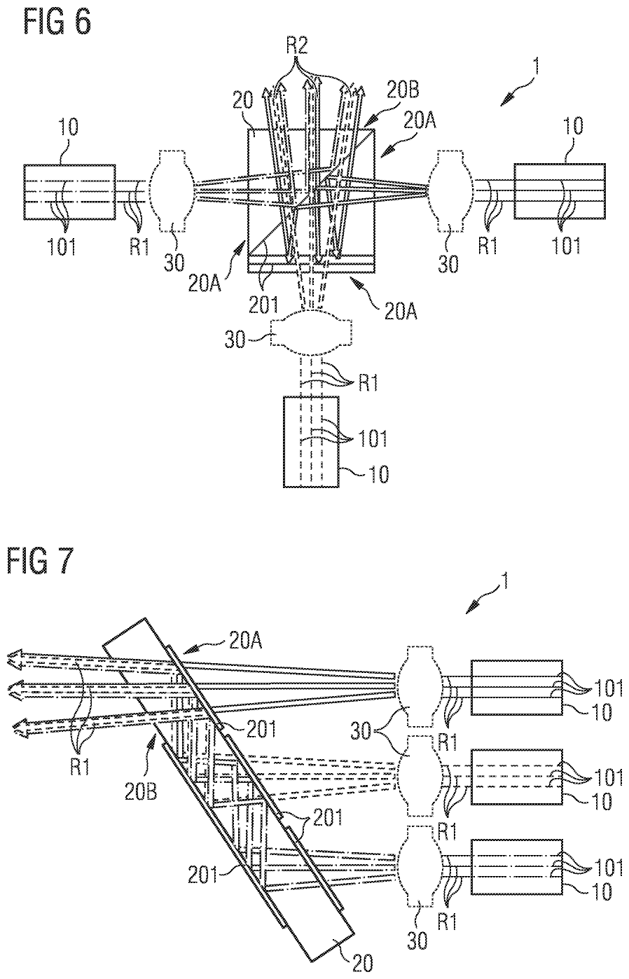

FIG. 6 shows a schematic top view of an optoelectronic assembly 1 according to the sixth exemplary embodiment. Essentially, the sixth exemplary embodiment corresponds to the first exemplary embodiment shown in FIG. 1. Unlike the first exemplary embodiment, the optical superpositioning element 20 comprises three radiation inlet surfaces 20A. Furthermore, the optical superpositioning element 20 comprises two reflective surfaces 201 and can thus be manufactured in a particularly simple manner. The optical superpositioning element 20 is formed in the shape of a cube and is thus particularly compact and stable. The reflective surfaces 201 are designed as z/4-platelets and change a polarization of an incident electromagnetic radiation.

FIG. 7 shows a schematic top view of an optoelectronic assembly 1 according to the seventh exemplary embodiment. Essentially, the seventh exemplary embodiment is the same as the first exemplary embodiment shown in FIG. 1. The optical superpositioning element 20 includes a plurality of reflective surfaces 201 on the radiation inlet surface 20A and on the side of the optical superpositioning element 20 opposite to the radiation inlet surface 20A.

Superposition of the inlet beam bundles R1 of the semiconductor laser components 10 in multiple outlet beam bundles R2 with different exit angles β is also possible with optical superpositioning elements 20 formed according to the second, third, fourth, fifth, sixth or seventh exemplary embodiments shown in FIGS. 2 to 7.

The invention is not limited by the description based on the embodiments. Rather, the invention encompasses any new feature as well as any combination of features, which in particular includes any combination of features in the patent claims, even if this feature or combination itself is not explicitly stated in the patent claims or embodiments.

1. An optoelectronic assembly comprising:
at least two semiconductor laser components configured to emit electromagnetic radiation, and
an optical superpositioning element having at least one radiation inlet surface and one radiation outlet surface, wherein
an optical element is assigned to each semiconductor laser component,
each semiconductor laser component emits an inlet beam bundle or a plurality of spatially separated inlet beam bundles,
all inlet beam bundles of a semiconductor laser component pass the respectively associated optical element, a plurality of inlet beam bundles emitted by a semiconductor laser component being fanned out with respect to one another after passing through the optical element in such a way that the inlet beam bundles enter the optical superpositioning element at different entry angles, and
inlet beam bundles from different semiconductor laser components emerge from the radiation outlet surface of the optical superpositioning element in a plurality of outlet beam bundles superimposed with each other.

2. The optoelectronic assembly according to claim 1, wherein the optical elements are a part of the optical superpositioning element.

3. The optoelectronic assembly according to claim 1, in which the optical elements have a distance from the optical superpositioning element.

4. The optoelectronic assembly according to claim 3,
wherein the distance of each optical element is adjusted such that the inlet beam bundles from different semiconductor laser components emerge from the radiation outlet surface of the optical superpositioning element in common outlet beam bundles superposed with each other.

5. The optoelectronic assembly according to claim 1,
wherein each semiconductor laser component comprises a plurality of waveguides each emitting an inlet beam bundle.

6. The optoelectronic assembly according to claim 5,
wherein the waveguides of a semiconductor laser component are independently drivable.

7. The optoelectronic assembly according to claim 1,
in which different inlet beam bundles of a semiconductor laser component have different main wavelengths.

8. The optoelectronic assembly according to claim 1,
in which corresponding inlet beam bundles of different semiconductor laser components have a different main wavelength.

9. The optoelectronic assembly according to claim 8,
wherein the main wavelengths of inlet beam bundles of different semiconductor laser components differ by at least 10 nm, preferably by at least 20 nm.

10. The optoelectronic assembly according to claim 1,
in which differences in the main wavelengths of the inlet beam bundles of each of a semiconductor laser component differ from one another by at least 0.5 nm.

11. The optoelectronic assembly according to claim 1,
wherein at least one beam of an inlet beam bundle impinges on the optical element outside an optical axis of the optical element.

12. The optoelectronic assembly according to claim 1,
wherein the optical elements are formed with the same material and/or have the same geometrical dimensions.

13. The optoelectronic assembly according to claim 1,
in which the optical elements are formed as collimating lenses.

14. The optoelectronic assembly according to claim 1,
wherein the semiconductor laser components emit equal numbers of inlet beam bundles.

15. The optoelectronic assembly according to claim 1,
wherein at least one semiconductor laser component has a constant waveguide distance.

16. The optoelectronic assembly according to the claim 15,
wherein the waveguide distances of all semiconductor laser components are equal.
